(19) United States
(12) Patent Application Publication
(10) Pub. No.: US 2014/0230898 A1
(43) Pub. Date: Aug. 21, 2014

(54) Framed Device, Seal, and Method for Manufacturing Same

(71) Applicant: Saint-Gobain Performance Plastic Chaineux, Chaineux (BE)

(72) Inventors: Georges Moineau, Battice (BE); Ahmet Comert, Herve (BE); Ronny R. Senden, Maasmechelen (BE); Philippe Pasleau, Jupille (BE); Dino Manfredi, Lummen (BE)

(73) Assignee: Saint-Gobain Performance Plastic Chaineux, Chaineux (BE)

(21) Appl. No.: 14/266,359

(22) Filed: Apr. 30, 2014

Related U.S. Application Data
(63) Continuation of application No. 12/493,555, filed on Jun. 29, 2009.
(60) Provisional application No. 61/077,521, filed on Jul. 2, 2008.

(51) Int. Cl. H01L 31/042

(52) U.S. Cl. CPC H01L 31/0424
USPC 136/259

(57) ABSTRACT

The disclosure is directed to a framed device. The framed device includes a substrate, a frame, and a seal. The substrate has a first length, a first width, and a peripheral edge. The frame has a second length, a second width, and a groove that runs along the second length and the second width of the frame. The groove is substantially engaged with the peripheral edge of the substrate. The seal is disposed within the groove of the frame, wherein the seal runs contiguously from the substrate to the frame and the seal includes a foamed polymer.

### CROSS-REFERENCE TO RELATED APPLICATIONS

The present application is a continuation and claims priority to U.S. patent application Ser. No. 12/493,555, filed Jun. 29, 2009, entitled “FRAMED DEVICE, SEAL, AND METHOD FOR MANUFACTURING SAME,” naming inventors Georges Moineau, Ahmet Comert, Ronny Senden, Philippe Pasleau and Dino Manfredi, which application claims priority from U.S. Provisional Patent Application No. 61/077,521, filed Jul. 2, 2008, entitled “FRAMED DEVICE, SEAL, AND METHOD FOR MANUFACTURING SAME,” naming inventors Georges Moineau, Ahmet Comert, Ronny Senden, Philippe Pasleau, and Dino Manfredi, which applications are incorporated by reference herein in their entirety.

### TECHNICAL FIELD OF THE DISCLOSURE

This application in general relates to seals, framed devices and methods for manufacturing framed devices.

### BACKGROUND

As economies around the world grow, demand for energy is increasing. As a result, the price of traditional fossil fuel energy sources is increasing. However, increased usage of fossil fuel sources has disadvantages such as detrimental environmental impact and theorized limits in supply.

Governments and energy industries are looking toward alternative energy sources for fulfilling future supply requirements. However, alternate energy sources have a higher per kilowatt-hour cost than traditional fossil fuel sources. One such alternate energy source is solar power. In typical solar power systems, photovoltaic devices absorb sunlight to produce electrical energy. Typical photovoltaic devices include polymer laminates and the like and glass that is sealed and held together in a framed structure. Due to the increasing demand of photovoltaic devices, there is a need for reducing the cost of these modules.

Typical devices are sealed and assembled by placing a polymer laminate and/or glass inside the frame. Generally, the polymer laminate and frame are sealed by the use of a liquid sealant or a double-sided tape. However, liquid sealants and tape can be messy, wasteful, and labor intensive. For example, excess liquid sealants need to be removed from the module and the device must be stored carefully to allow proper curing of the sealant. Double-sided tape may be particularly difficult to apply, especially on the corners of the photovoltaic device. As such, an improved photovoltaic device would be desirable.

### SUMMARY

In one particular embodiment, the disclosure is directed to a framed device. The framed device includes a substrate, a frame, and a seal. The substrate has a first length, a first width, and a peripheral edge. The frame has a second length, a second width, and a groove that runs along the second length and the second width of the frame. The groove is substantially engaged with the peripheral edge of the substrate. The seal is disposed within the groove of the frame, wherein the seal runs contiguously from the substrate to the frame and the seal includes a foamed polymer.

In another exemplary embodiment, the disclosure is directed to a photovoltaic device including a substrate, a frame, and a seal. The substrate has a first length, a first width, and a peripheral edge. The frame has a second length, a second width, and a groove that runs along the second length and the second width of the frame, wherein the groove is substantially engaged with the peripheral edge of the substrate. The seal is disposed within the groove of the frame and runs contiguously from the substrate to the frame. The seal includes a foamed poly-alpha-olefin.

In a further exemplary embodiment, the disclosure is directed to a method of manufacturing a framed device. The method includes heating a polymer, foaming the polymer to provide a foamed polymer, applying the foamed polymer with a groove of a frame, and inserting the substrate within the groove to form a seal between the groove and the substrate.

In another embodiment, the disclosure is directed to a seal. The seal includes a poly-alpha-olefin polymer, wherein the poly-alpha-olefin polymer is foamed.

### BRIEF DESCRIPTION OF THE DRAWINGS

FIG. 1 illustrates an exemplary embodiment of a framed device; and

FIG. 2 illustrates an exemplary embodiment of a photovoltaic device.

### DETAILED DESCRIPTION

In one embodiment, a framed device is provided that includes a substrate, a frame, and a seal. The substrate has a first length, a first width, and a peripheral edge. The frame has a second length, a second width, and a groove that runs along the second length and the second width of the frame. The groove is substantially engaged with the peripheral edge of the substrate. The seal is disposed within the groove of the frame, wherein the seal runs contiguously from the substrate to the frame and the seal includes a foamed polymer. The foamed polymer forms a substantially water impermeable seal between the frame and the substrate.

Sealant compositions suitable as the foamed polymer include, for example, thermoplastic polymers, elastomers, natural and synthetic rubber, silicones, thermoset polymers, such as cross-linkable thermoset polymers, hot melt adhesives, butyls, and combinations thereof. Exemplary polymers include polyalkylenes (e.g., polyethylene, polypropylene and polybutylene), poly(alpha)olefins including, e.g., homo-, co- and terpolymers of aliphatic mono-1-olefins (alpha olefins) (e.g., poly(alpha)olefins containing from 2 to 10 carbon atoms), homogeneous linear or substantially linear interpolymers of ethylene having at least one C₃ to C₂₀ alphaolefin, polyisobutylenes, poly(alkylene oxides), poly(phenylenediamine terephthalamide), polyesters (e.g., polyethylene terephthalate), polyacrylates, polymethacrylates, polyacrylamides, polyacrylonitriles, copolymers of acrylonitrile and monomers including, e.g., acrylonitrile butadiene rubber (NBR), butadiene, styrene, polymethyl pentene, and polyphenylene sulfide (e.g., styrene-acrylonitrile, acrylonitrile-butadiene-styrene, acrylonitrile-styrene-butadiene rubbers), polysulfides, polyimides, polyamides, copolymers of vinyl alcohol and ethylenically unsaturated monomers, polyvinyl acetate (e.g., ethylene vinyl acetate (EVA)), polyvinyl alcohol, vinyl chloride homopolymers and copolymers (e.g., polyvinyl chloride), polysiloxanes, polyurethanes, polystyrene, and combinations thereof, and homopolymers, copolymers and terpolymers thereof, and mixtures thereof. In an embodiment, the polymer is free from isocyanates. In an embodiment, the foamed polymer is a polyurethane. In an alternative embodiment, the foamed polymer is a poly-alpha-olefin. In another embodiment, the foamed polymer is a blend of ethylene propylene diene monomer (EPDM) rubber and polypropylene; for example, the polymers which are obtainable under the trade name SANTOPRENE®.

In a particular embodiment, any suitable polymer may be used that has an initial melt viscosity of about 10 mPa·s to about 200,000 mPa·s at 190° C. In an embodiment, the polymer has an initial melt viscosity of about 500 mPa·s to about 50,000 mPa·s at 190° C. In a particular embodiment, the polymer is adhesive as a raw material, i.e. prior to foaming.

In an embodiment, the polymer is a poly-alpha-olefin. Typically, the poly-alpha-olefin includes homo-, co- and terpolymers of aliphatic mono-1-olefins (alpha olefins) (e.g., poly(alpha)olefins containing from 2 to 10 carbon atoms). In an embodiment, the poly-alpha-olefin may include an alpha-olefin having 4 to 10 carbon atoms in addition to, or instead of 1-butene such as, for example, 3-methyl-1-butene, 1-pentene, 1-hexene, 3,3-dimethyl-l-butene, 4-methyl-l-pentene, 1-heptene, 1-octene or 1-decene. In an exemplary embodiment, the poly-alpha-olefin contains about 0.1% to about 100% by weight of alpha-olefins containing 4 to 10 carbon atoms. In an embodiment, propene may be present at an amount of about 0.1% to about 98% by weight, such as about 30% to about 80% by weight, based on the total weight of the poly-alpha-olefin. In an embodiment, ethene may be present at an amount of about 1% to about 95% by weight, such as about 0% to about 10% by weight, or even about 3% to about 8% by weight, based on the total weight of the poly-alpha-olefin. In an embodiment, the ratio of different monomers may be adjusted depending on the properties desired, such as hardness, melt viscosity, and crystallinity. Suitable poly-alpha-olefins include terpolymers such as propene/1-butene/ethene terpolymers and propene/1-butene copolymers; for example, the polymers which are obtainable under the trade name VESTOPLAST®.

In an embodiment, the poly-alpha-olefin is grafted to increase the adhesion of the poly-alpha-olefin to a substrate. Any known adhesion promoting grafting species may be used. Any amount of a grafting species may be used that substantially improve the adhesion of the poly-alpha-olefin to the substrate. In an embodiment, the poly-alpha-olefin may be grafted with an anhydride, such as maleic anhydride (e.g. VESTOPLAST 308), or a silane.

In an embodiment, an unsaturated silane is grafted on the poly-alpha-olefin. In a particular embodiment, the silane has at least one olefinic double bond and one to three alkoxy groups bonded directly to the silicon. In an embodiment, the silane to be grafted has three alkoxy groups bonded directly to the silicon. Vinyltrimethoxysilane (VTMO), vinyltriethoxysilane, vinyl-tris(2-methoxyethoxy)silane, 3-methacryloyloxypropyltrimethoxysilane (MEMO; H₂C═C(CH₃)COO(CH₂)₃—Si(OCH)₃), 3-methacryloyloxypropyltriethoxysilane, vinyldimethylmethoxysilane or vinylmethyldibutoxysilane may be mentioned by way of example. In an embodiment, silanes include those which the double bound is not directly linked to the silane, e.g.. allyltrimethoxy silane, allyltriethoxy silane, and the like. In the grafting, the silane is typically used in amounts of up to about 20% by weight, such as about 0.1% to about 10% by weight, such as about 0.5% to about 5% by weight, based on the poly-alpha-olefin. The silane on the poly-alpha-olefin improves the adhesion of the foamed polymer without the need for any primer.

The unsaturated silane is typically grafted onto the polyolefin by methods known to those of ordinary skill in the art, for example in solution or in the melt, with the addition of a free radical donor being used in sufficient amount. In an example, the silane group is hydrolyzed forming silanol groups. The polymer can subsequently be cross-linked, e.g. by silanol condensation or by reaction with hydroxy- functional polymers. Silanol condensation reactions can be catalyzed by suitable silanol condensation catalysts such as organometallics, organic bases, acidic minerals and fatty acids. Exemplary organometallics include dibutyl tin dilaurate or tetrabutyl titanate. The catalyst may optionally be used in an amount of about 0.01% to about 1.0%, for example, from about 0.01% to about 0.5% by weight of the polymer.

In general, the poly-alpha-olefin is largely amorphous; that is, it has a degree of crystallinity of not more than 45%, as determined by X-ray diffraction. In an embodiment, the poly-alpha-olefin has a degree of crystallinity of not more than 35%. The crystalline fraction of the substantially amorphous poly-alpha-olefin can be estimated, for example, by determining the enthalpy of fusion by means of the DSC method. Typically, a weighed sample is first heated from about −100° C. to about +210° C. at a heating rate of about 10° C./min and then cooled again to about −100° C. at a rate of about 10° C./min. After the thermal history of the sample has been eliminated in this manner, heating is again effected at a rate of about 10° C./min to about 210° C., and the enthalpy of fusion of the sample is determined by integrating the melt peak which is attributable to the crystallite melting point Tₘ. Preferably, the enthalpy of fusion of the substantially amorphous polyolefin is not more than about 100 Joules/gram (J/g), more preferably not more than about 60 J/g and particularly preferably not more than about 30 J/g.

The grafted substantially amorphous polyolefin typically has an initial melt viscosity in the range from about 1000 to about 30,000 mPa·s, such as about 2000 to about 20,000 mPa·s, and about 2000 to about 15,000 mPa·s.

The foamed polymer may further include additives to impart particular properties on the foam. For instance, pigments, fillers, catalyst, plasticizer, biocide, flame retardant, antioxidant, surfactant, tackifiers, adhesion promoting additives, and the like may be added. Exemplary pigments include organic and inorganic pigments. Suitable fillers include, for instance, silica, precipitated silica, talc, calcium carbonates, aluminasilicates, clay, zeolites, ceramics, mica, aluminium or magnesium oxide, quartz, diatomaceous earth, thermal silica, also called pyrogenic silica, and nonpyrogenic silica. The fillers may also be silicates such as talc, mica, kaolin, glass microspheres, or other mineral powders such as calcium carbonate, mineral fibers, or any combination thereof. Exemplary plasticizers include paraffinic oils, naphthenic oils, low molecular weight poly-l-butene, low molecular weight polyisobutene, and combinations thereof. In a particular embodiment, the foamed polymer includes adhesion promoting additives such as functional silanes or other adhesion promoters. Exemplary silanes include 3-aminopropyltrimethoxy silane, 3-(trimethoxysilyl)propyl methacrylate, 3-glycidoxypropyltrimethoxy silane, and n-octyltrimethoxy silane. The adhesion promoter may optionally be used in an amount of about 0.01% to about 5.0%, for example from about 0.01% to about 2.0% by weight of polymer.

The substrates of the framed device may be formed of rigid substrates or flexible substrates. As stated earlier, the substrate has a first length and a first height and may be of any reasonable shape. For instance, the substrate may be square, rectangular, etc. Any exemplary rigid substrate may be used. For example, the frame device may be a photovoltaic device wherein the rigid substrates include crystalline silicon polymeric substrates. The photovoltaic device to be framed may include exterior surfaces of glass, metal foil, or polymeric films such as fluoropolymers, polyolefins, or polyesters and the like. Further any number of substrates may be envisioned. In an embodiment, it is possible to adapt the actual shape of the substrates of the device, in order to improve the effectiveness of the sealing and/or to make it easier to fit the seal. Thus, it is possible to use substrates whose peripheral edge is beveled, thereby making it possible to define a wider peripheral edge, which no longer has a simple rectangular cross section but which has an at least partly trapezoidal cross section, for example. The beveled peripheral edge provides a greater surface area to come in contact with the foamed polymer.

The frame of the framed device that encompasses the periphery of the substrate may be made of any reasonable material that retains its rigidity under external or internal stress. In an embodiment, the frame may be metal, polymer or composite material. An exemplary metal is aluminum. The cross section of the frame may be square, rectangular, etc., like that of the abovementioned substrate. The frame has a second length and a second height that is greater than the first length and the first height of the substrate. The groove runs along the second length and the second height of the frame. As stated earlier, the foamed polymer seal is disposed within the groove. Further, the substrate is disposed within the foamed polymer seal such that the groove of the frame houses the substrate and the polymer seal. The groove may be of any shape for its cross-section. Typically, the groove is a channel. In an embodiment, the groove has a rectangular cross-section or a trapezoidal cross-section. Advantageously, at least one part of the bearing surfaces via which the frame bears on the substrate is coated with one or more foamed polymer seals. This frame may be made as one piece, or as several parts which are butted together during fitting.

Framed devices include, for example, any device or assembly where water vapor impermeability and significant mechanical strength is desired. Exemplary framed assemblies include, for example, electronic devices, photovoltaic devices, insulating glass assemblies, and the like. For instance, photoactive devices, such as electronic devices, may be formed on the substrates using techniques such as semiconductor processing techniques and printing techniques. These photoactive devices may be connected using conductive interconnects, such as metallic interconnects and/or semiconductor interconnects. Metallic interconnects, for example, include gold, silver, titanium, or copper interconnects. Further, any other material, substrate, or the like, used to construct a framed device, such as a photovoltaic device may be envisioned.

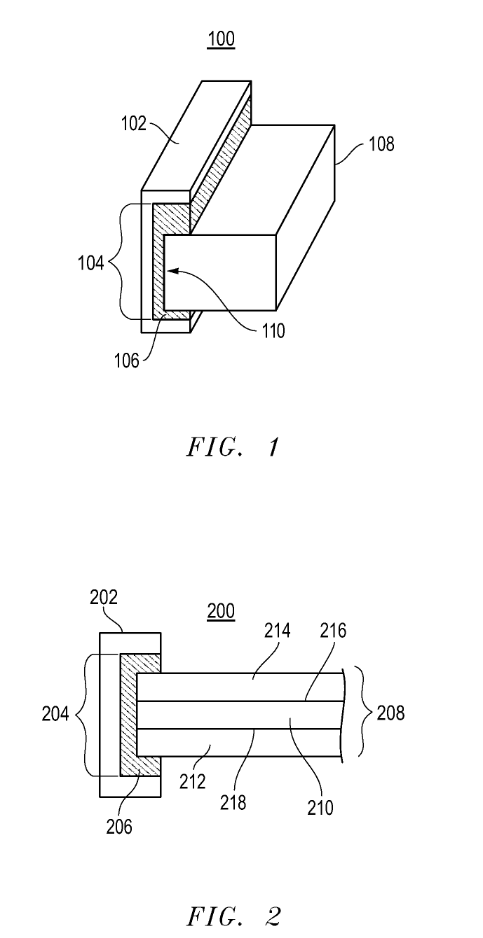

FIG. 1 illustrates an exemplary embodiment of a cross-section of a framed device. The framed device 100 includes a frame 102 having a groove 104. The foamed polymer 106 is directly in contact with and sandwiched between both the frame 102 and the substrate 108. As illustrated, the foamed polymer 106 substantially fills the groove 104, particularly, with the substrate 108 housed within the groove 104. Further, the foamed polymer 106 can be applied such that the foamed polymer 106 is flush with the frame 102 without any excessive overhang of the foamed polymer 106 out of the periphery of the frame 102 or onto the substrate 108. As illustrated, the peripheral edge 110 of the substrate has a rectangular cross-section, similar to the cross-section of the groove 104 of the frame 102. A groove is typically configured to contain the substrate within two opposing sides of the groove. The groove may have a variety of shapes including rectangular, circular, trapezoidal, triangular or any shape configured to receive the device to be framed. In one exemplary embodiment, the entrance may have a slight bend inwards to guide the panel and also limit overflow. In an embodiment, any configuration to hold the substrate in the device is envisioned. In an embodiment, the device may include a seat, such as an L-shaped seat where the substrate is configured to sit on the L-shaped seat. With an L-shaped seat, the substrate is typically not contained within two opposing sides but is held within the device with the adhesive properties of the foamed polymer.

FIG. 2 illustrates an exemplary embodiment of a photovoltaic device 200. The photovoltaic device 200 includes a frame 202 having a groove 204. The foamed polymer 206 is directly in contact with and sandwiched between both the frame 202 and the substrates 208 of the photovoltaic device 200. As illustrated, the foamed polymer 206 substantially fills the groove 204, particularly, with the substrate 208 housed within the groove 204. Further, the foamed polymer 206 can be applied such that the foamed polymer 206 is flush with the frame 202 without any excessive overhang of the foamed polymer 206 out of the periphery of the frame 202 or onto the substrate 208.

The substrate 208 includes a plurality of layers as shown. The photovoltaic device 200 includes a photovoltaic layer 210 surrounded by an electrically insulating back sheet 212 and a protective layer 214, such as an anti-reflective glass. A photovoltaic layer 210 includes an active surface 216 and a backside surface 218. When in service, the photovoltaic layer 210 may receive electromagnetic radiation through the active surface 216 and using devices, such as semiconductor devices formed in the photovoltaic layer 210, convert the electromagnetic radiation into electric potential. In general, light or electromagnetic radiation transmitted or passed to the backside surface 218 does not result in the production of a significant electric potential.

The photovoltaic layer 210 may further include protective films (not shown). In an embodiment, a protective film may overlie the active surface 216 of the photovoltaic layer 210 and a protective film may underlie the backside 218 of the photovoltaic layer 210. The protective film used is typically dependent upon the framed device. For instance, the protective film may include a polymer, a metal, or any film envisioned. Any method of adhering the film to the substrate may also be envisioned. In addition, the photovoltaic layers 210 may or may not include a hard coating layer (not shown) on the active surface 216 that acts to protect the photovoltaic layer or layers during additional processing.

The framed device may be formed through a method which includes foaming the polymer. Prior to foaming, the polymer is heated to a temperature to melt the polymer. For instance, the polymer is heated to its melt temperature. In an embodiment, the polymer is heated to a temperature as not to degrade the polymer. For instance, the polymer is heated to a temperature not greater than about 250° C. In an exemplary embodiment, the polymer is poly-alpha-olefin due to its relatively low melt temperature compared to polymers such as polypropylene and blends of polypropylene/EPDM. In an embodiment, the polymer may be melted using a drum unloader. In a particular embodiment, the polymer has adhesive properties to a substrate once the polymer is melted but even prior to foaming.

The polymer is foamed by any reasonable means. The melted polymer may be pumped, metered, and mixed with a determined amount of any useful foaming agent. For instance, polymer is foamed by mixing the heated polymer with any useful blowing agent or an inert gas. Exemplary blowing agents include, for example, azodicarbonamide (ADC), 1,1′-azobisformamide (AIBN), oxybisenzenesulphonylhydrazide (OBSH), methylal, and the like. Exemplary inert gases include, for example, air, nitrogen (N₂), carbon dioxide (CO₂), chlorodifluoromethane (HCFC), and the like. In an embodiment, the gas is injected and mixed in the molten material. In an embodiment, the polymer can be foamed by using equipment such as SEVAFOAM® (obtained from Seva) or FOAMIX® and ULTRAFOAM MIX® (obtained from Nordson). Typically, the polymer is foamed such that it has an expansion ratio of about 1 to about 10, such as about 2 to about 7.

In an embodiment, the foamed polymer is applied within the groove of the frame to form a seal between the groove and the substrate. In an embodiment, the foamed polymer may be applied by any reasonable means such as manually or by electronic or robotic means. In an embodiment, the foamed polymer may be applied by injection or extrusion. Measures may be taken to ensure that all the foamed polymer is housed in the peripheral groove described above. This then results in a device wherein the foamed polymer is flush and substantially fills the groove. Further, the seal does not “overhanging” the substrate, this being both aesthetically attractive and practical when inserting the substrate. In a particular embodiment, the foamed polymer is substantially uniform, i.e. the thickness of the polymer does not vary by more than about 10%. In an embodiment, the foamed polymer may be beaded. In an embodiment, the foam polymer is applied via a robotic mechanism.

Further, the substrate is inserted within the foamed polymer. The substrate is inserted within the foamed polymer prior to the point at which the foamed polymer cures. Cure may occur by any reasonable means such as moisture curing, thermal curing, or the like. Typically, the time period of cure is dependent upon the polymer chosen and the compressibility of the polymer. For instance, the substrate is inserted within the foamed polymer within 1 second to about 10 minutes of inserting the foamed polymer within the groove of the frame. In an embodiment, the substrate is inserted within the foamed polymer at less than about 10 minutes, such as less than about 5 minutes, such as less than about 2 minutes of inserting the foamed polymer within the groove of the frame. Further, when the substrate is inserted within the foamed polymer, the foamed polymer compresses to avoid overflow of the material. In one exemplary embodiment, the foamed polymer has an open-time of about 1 minute to about 10 minutes, such as greater than about 2 minutes, greater than about 5 minutes, or even greater than about 10 minutes. The open-time of the material is defined as the time needed for the material to solidify/set without insertion of the panel. Time zero is just after application of the material in the groove. Once beyond the open-time, it difficult to insert the panel correctly and less adhesion will be obtained.

Another desired feature is the time-to-set, i.e. the time the material needs to achieve sufficient integrity or, in other words, to set once the panel is inserted. In an exemplary embodiment, the time-to-set for the foamed polymer is less than or equal to about 1 min, such as less than or equal to about 30 seconds, and even less than or equal to about 15 seconds. The time-to-set enables the process to be sped up compared to the current silicone based process. In contrast, the current, conventional silicone based process can take a time period of about 30 minutes up to several days to set.

In an embodiment, the foamed polymer may also be placed on the peripheral edge of the substrate via any means. The frame may then be placed on the substrate. In an embodiment, no extra heating is used. In another embodiment, further heating of the frame and/or the foam may occur to soften the foam if, for instance, the foam hardens too quickly or assembly of the frame requires more time. In an embodiment, external cooling of the assembly may occur to, for instance, speed up the assembly process. In another embodiment, external cooling of the assembly is not used. Notably, the application of the foamed sealant is efficient. Advantageously, application of the foamed polymer does not require any need for removing, wiping, or cleaning of any excess sealant. In contrast, conventional polymers such as silicone adhesives typically require cleaning after inserting the panel into the groove. As stated earlier, the foamed polymer is compressible, substantially uniform, and does not have any excess sealant overflow.

In an exemplary embodiment, the foamed polymer is substantially impermeable to water vapor. For instance, the foamed polymer advantageously has a water vapor permeability of less than or equal to about 5 g/m²/24 h, such as less than about 4 g/m²/24 h, or less than about 3 g/m²/24 h. In an exemplary embodiment, the foamed polymer has a water vapor permeability of less than or equal to about 0.5 g/m²/24 h, or even less than or equal to about 0.25 g/m²/24 h, according to the ASTM E 9663 T standard; meaning that they are particularly impermeable to water.

Further, the foamed polymer has substantial adhesion to the substrate of the framed device. The foamed polymer preferably exhibits less than 50% adhesion failure, less than 20% adhesion failure, or even is free of adhesion failure. In a particular embodiment, the foamed polymer exhibits substantial adhesion without the need for pre-treating the surface of a material that the foamed polymer contacts. It is important that the polymer be chosen such that it is intrinsically impermeable but also adheres very well to the materials with which it is in contact, so as to prevent the creation of diffusion paths at the interface between the seal and the material to be sealed, so as to avoid any delamination of the seal. In an embodiment, the foamed polymer meets or exceeds expectations regarding adhesion required for photovoltaic frame applications. In a particular embodiment, the foamed polymer is substantially self-adhesive to the substrate and the frame.

Further, the foamed polymer has sufficient flexibility to allow for expansion/contraction due to thermal cycling and any difference of coefficient of temperature expansion between two different materials, for example, the substrate and the frame.

In a particular embodiment, the foamed polymer may be used for any suitable instance where properties such as water vapor impermeability, adhesion, and/or mechanical strength are needed. In an exemplary embodiment, the foamed poly-alpha-olefin may be used for a variety of instances where these properties are desired. For instance, the foamed polymer may not only be used for framed devices but also for any seal applications. Uses may be found in industries such as in automotives, electronics, construction, upholstery, etc. In particular, the foamed polymer may be used for gaskets.

### EXAMPLES

### Example 1

The following example describes a representative composition and measurement of set-time and open-time. Compositions and values can be seen in Table 1.

TABLE 1
Composition and values:

| | Composition 1 (wt %) | | Composition 2 (wt %) | |
|---|---|---|---|---|
| Vestoplast 206 | 40.3 | | 60.4 | |
| Vestoplast 508 | 59.4 | | 39.3 | |
| Irganos 1076 | 0.2 | | 0.2 | |
| Irgafos 168 | 0.05 | | 0.05 | |
| Tinuvin 326 | 0.05 | | 0.05 | |
| Time to set | <30 | s | <15 | s |
| Open time at 160° C. | 3.5 | min | 2 | min |

Test methods and terms are described below:

“Time to set” is the time needed for the material to have sufficient dimensional stability after insertion of device such that the device can be lifted via the frame without sliding of the device

Conditions for the “Open time” test method include providing a long sheet of paper. The long sheet of paper is provided, for example, by taping three to four A4 papers together. A 50 μm metallic calibrator, or coating draw down blade is placed at the one end of the paper sheet.

300 g of polymer or polymer mixture are heated under nitrogen at 160° C. After about 60 to 90 minutes, about half of the molten material is poured just in front of the calibrator and the calibrator is drawn down the sheet to produce a 50 μm thick film. As soon as the end of the sheet is reached, time is recorded. 2.5×2.5 cm papers (same type) are firmly pressed onto the film at specific times: 15, 30, 45 seconds, and 1, 1.5, 2, 2.5, 3, 3.5, 4.5, 5, 6, 7, 8, 9, 10 and 15 minutes. After an additional 5 minutes the small papers are removed with a pair of tweezers. The open-time is defined as the longest time at which:
a small paper cannot be removed from the polymer film for at least 75% of its total surface, or
if removed, then at least 75% of the peeled area shows cohesive failure within the paper.

### Example 2

An exemplary crosslinking test and method is described. The composition and values can be seen in Table 2.

TABLE 2
Composition and values

| | Composition 2 (wt %) | Composition 3 (wt %) |
|---|---|---|
| Vestoplast 206 | 60.4 | 60.2 |
| Vestoplast 508 | 39.3 | 39.2 |
| Irganos 1076 | 0.2 | 0.2 |
| Irgafos 168 | 0.05 | 0.05 |
| Tinuvin 326 | 0.05 | 0.05 |
| Dabco T-12N | none | 0.3 |
| Crosslinking time | >>2 months | 7 days |

The rheological behaviour of the polymer and polymer mixtures is studied using a Paar Physica UDS200 rheometer. Measurements are performed on 1 mm thick samples under nitrogen using a 1 Hz deformation mode and a parallel plate configuration. The initial normal force at 23° C. is set at about 0.25-0.5 N. The samples are analysed between about 30 and 200° C. at heating rate of about 10° C./min. The samples are die cut out of preformed sheets.

Die-cut samples are allowed to crosslink at 23° C./50% RH and the storage modulus between 140-200° C. is monitored as a function of time. At these temperatures, all crystallites are molten and therefore all increases in storage modulus are directly related to an increase in stiffness due to the crosslinking process.

The “crosslinking time” is the time at which the increase in storage modulus levels off.

### Example 3

Examples for 90° peel adhesion tests are as follows:

TABLE 3
Composition and values

| | Composition 3 (wt %) | Composition 4 (wt %) |
|---|---|---|
| Vestoplast 206 | 60.2 | 59.6 |
| Vestoplast 508 | 39.2 | 38.8 |
| Irganos 1076 | 0.2 | 0.2 |
| Irgafos 168 | 0.05 | 0.05 |
| Tinuvin 326 | 0.05 | 0.05 |
| Dabco T-12N | 0.3 | 0.3 |
| 3-(trimethoxysilyl)propyl | None | 1.0 |
| methacrylate | | |
| Adhesion on glass | 13.8 ± 3.1 | 40.1 ± 4.3 |
| (N/cm) | | |
| Adhesion on Tedlar | 16.0 ± 2.6 | 43.3 ± 2.5 |
| (N/cm) | | |
| Adhesion on anodized | 11.0 ± 1.2 | 35.2 ± 2.1 |
| Al (N/cm) | | |

The 90° peel tests are performed using Hounsfield tensile equipment. Prepared samples are stored at about 23° C. and about 50% relative humidity (RH) during two weeks prior to measurement.

Both the Aluminum and PV test bars have the following dimensions: 50×150 mm. Test bars are cleaned with acetone and a 50/50 v/v % solution of isopropanol and water prior to assembly. The compositions are applied using a standard hot melt gun to the test bars in such a way that adhesion is assured over about 100 mm. The width was about 15 mm. Thickness was about 0.8 mm. To prevent adhesion on the remaining 50 mm, a non-adhesive glass cloth is applied on a surface area of 50×50 mm at one of the extremities of the test bar.

The tests are performed at 50 mm/min and at about 23° C. and about 50% RH. Measurements are performed on 3 specimens per sample.

### Example 4

Examples for the pluck performance is as follows:

TABLE 4
Composition and values

| | Composition 5 (wt %) |
|---|---|
| Vestoplast 206 | 50.4 |
| Vestoplast 508 | 48.5 |
| Irganos 1076 | 0.2 |
| Irgafos 168 | 0.05 |
| Tinuvin 326 | 0.05 |
| Dabco T-12N | 0.3 |
| 3-aminopropyltrimethoxy | 0.5 |
| silane | |
| Maximal pluck force (N/cm) | 79.8 ± 5.1 |
| Material quantity (mg/cm) | 162.5 |
| Foam density prior to test bar | 380 |
| insertion (kg/m³) | |

The pluck tests are performed using Hounsfield tensile equipment. Prepared samples are stored at about 23° C. and about 50% RH during two weeks prior to measurement.

The PV test bars have the following dimensions: 25×75 mm. A PV Aluminum frame is used to insert the test bars into a groove (6×8 mm). Test bars and grooves are cleaned with acetone and a 50/50 v/v % solution of isopropanol and water prior to assembly. Foam is applied using the UltraFoam Mix from Nordson and a dispensing gun attached to a robot. 5 cm long foam beads are applied in the groove for each test bar. The test bars are manually inserted to a depth of 7 mm (1 mm from the bottom of the groove).

The tests are performed at 12.5 mm/min and at about 23° C. and about 50% RH. Measurements are performed on 3 specimens per sample.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A photoactive device comprising:
a substrate having a first length, a first width, and a peripheral edge, wherein the substrate comprises a glass;
a frame having a second length, a second width, and a groove that runs along the second length and the second width of the frame, wherein the groove is substantially engaged with the peripheral edge of the substrate; and
a seal comprising a foamed polymer having a water vapor permeability of about 5 g/m²/24 h or less, wherein the foamed polymer is disposed within the groove of the frame and wherein the foamed polymer runs contiguously from the substrate to the frame.

2. The device of claim 1, wherein the foamed polymer comprises a poly-alpha-olefin.

3. The device of claim 2, wherein the poly-alpha-olefin has a degree of crystallinity of not more than 45%, as determined by X-ray diffraction.

4. The device of claim 2, wherein the poly-alpha-olefin contains about 0.1% to about 100% by weight of alpha-olefins containing 4 to 10 carbon atoms.

5. The device of claim 4, wherein the poly-alpha-olefin is a terpolymer of ethylene, propylene, and 1-butene.

6. The device of claim 4, wherein the poly-alpha-olefin is a copolymer of propylene and 1-butene.

7. The device of claim 2, wherein the poly-alpha-olefin is silane grafted.

8. The device of claim 7, wherein the silane includes a silicon and one to three alkoxy groups bonded directly to the silicon.

9. The device of claim 7, wherein the silane is present in an amount of up to about 20% by weight, based on the weight of the poly-alpha-olefin.

10. The device of claim 2, wherein the poly-alpha-olefin is maleic anhydride grafted.

11. The device of claim 1, wherein the foamed polymer is polyurethane, modified silicone polymer, thermoplastic elastomer, polyethylene, polypropylene, a blend of ethylene propylene diene monomer (EPDM) rubber and polypropylene, acrylonitrile butadiene rubber (NBR), ethyl vinyl acetate (EVA), butyl, or combination thereof.

12. The device of claim 1, wherein the foamed polymer is substantially adhesive to the substrate and the frame.

13. The device of claim 1, wherein the peripheral seal is disposed in the groove by extruding or injecting the foamed polymer.

14. The device of claim 1, wherein the foamed polymer has an expansion ratio of about 1 to about 10.

15. The device of claim 1, wherein the foamed polymer has a time-to-set of less than or equal to about 1 minute.

16. The device of claim 1, wherein the foamed polymer has a water vapor permeability of less than about 4 g/m²/24 h, less than about 3 g/m²/24 h, less than or equal to about 0.5 g/m²/24 h, or less than or equal to about 0.25 g/m²/24 h.

17. The device of claim 1, wherein the frame is metal, polymer or composite material.

18. The device of claim 1, wherein the substrate further comprises a metal foil, a polymeric film, a crystalline silicon polymer, or combination thereof.

19. A photoactive device comprising:
a substrate having a first length, a first width, and a peripheral edge, wherein the substrate comprises a glass;
a frame having a second length, a second width, and a groove that runs along the second length and the second width of the frame, wherein the groove is substantially engaged with the peripheral edge of the substrate; and
a seal comprising a foamed polymer having a water vapor permeability of about 5 g/m²/24 h or less, the foamed polymer comprising a poly-alpha-olefin having a degree of crystallinity of not more than 45%, as determined by X-ray diffraction, wherein the foamed polymer is disposed within the groove of the frame and wherein the foamed polymer runs contiguously from the substrate to the frame.

20. The device of claim 19, wherein the poly-alpha-olefin is silane grafted, the silane including a silicon and one to three alkoxy groups bonded directly to the silicon.
